(19) United States
(12) Patent Application Publication
(10) Pub. No.: US 2009/0161311 A1
(43) Pub. Date: Jun. 25, 2009

(54) Top mount surface airflow heatsink and top mount heatsink component device

(75) Inventor: I-Shih Tseng, Taoyuan Hsien (TW)

Correspondence Address: WANG, HARTMANN & GIBBS, 1301 DOVE STREET, SUITE 1050, NEWPORT BEACH, CA, 92660, US

(73) Assignee: Chroma Ate, Inc, Taoyuan Hsien (TW)

(21) Appl. No.: 11/982,655

(22) Filed: Nov. 1, 2007

(30) Foreign Application Priority Data
Nov. 3, 2006 (TW) 095140847

(51) Int. Cl. H05K 7/20

(52) U.S. Cl. 361/679.47; 361/697; 361/679.52

(57) ABSTRACT

It's a type of top mount surface airflow heatsink, utilizing the upper ceiling wall separated by an air gap, working together with the upper surface of a heating device (microprocessor) producing an air current. It's a simple device, with a low cost using the Reynolds Equation Re=(ρuₘd)/μ≧2,500; with ρ being the fluid density, uₘ being the free-stream fluid velocity, d being the pipe distance or diameter, μ being the fluid viscosity. Since the airflow produces air turbulence, it causes the frequent heat exchanges in the air. It also causes the obvious temperature changes within the different layers of air. Therefore, it increases tremendously, the efficiency of dissipating the heat. It requires only the input of the air. The operation is simple and it allows the usage of even higher heat generating devices. Thus it promotes the alternative usage of this top mount heatsink device within the installation of circuit board components.

### FIELD OF THE INVENTION

This invention is a top mount heatsink device, specifically, a top mount surface airflow heatsink device.

### BACKGROUND OF THE INVENTION

With the increase advance and popularity of the semiconductor, the semiconductor circuit by itself is getting more complex and it requires more energy therefore, producing more heat. On the other hand, once the operating temperature reaches over 120 degrees Celsius, not only the silicon chips may be damaged, even the semiconductor components and the circuit board may melt under the extreme high temperature which may disrupt electrical conduct. Therefore, creating the problems of short-circuit.

Therefore, whether it's the mother-board, video card, or any other semi-conductor board, as shown in FIG. 1, on top of the heating semiconductor chip (10), it's applied a coating of heat conductor gel (14) to hold the heatsink (16) and the semiconductor chip together. If this is not good enough, a cooling fan (18) can be added on top of the heatsink, so the heat produced by the circuit board (12) and the semiconductor chip (10) can be dissipated through the heatsink (16). Therefore reducing the heat accumulation and preventing the damage to the semiconductor chip (10).

Furthermore, as shown in FIG. 2, a U.S. Pat. No. 6,603,658, this invention has an air duct (26), to direct the airflow from the fan (28), to provide a stable air current flowing toward the circuit board (22) and over the heat device, microprocessor (20). So the heat produced by the heat device, microprocessor (20) can be dissipated. As an example, it can reduce the internal temperature of a notebook device.

The air duct (26) as shown on FIG. 3, it's not directly attached to the heat device, microprocessor (20). The distance between the air duct (26) and heat device, microprocessor (20) is many times longer than the measurement of the opening width. Therefore, the airflow (280) from the air duct (26) with the laminar jet airflow will steadily move across the surface of the heat device, microprocessor (20), even creating a stagnation region between the surface of the heat device, microprocessor (20) and the contact area of the airflow, initiating a heat exchange. To maintain a stable laminar jet airflow, the previous patent using the Reynolds Equation Re=(ρuₘd)/μ≧2,500; with ρ being the fluid density, uₘ being the free-stream fluid velocity, d being the pipe distance or diameter, μ being the fluid viscosity.

Although, in relation to the high volume heat produced by the computer and electronic equipments, using the above mentioned laminar jet airflow method by itself, it'll not yield a satisfactory result. Especially, when using high complexity circuit components, and with the increased amounts of the electronic components being used in the circuit boards, it'll only increase the heat generated on specific isolated areas. The ability to effectively, disperse the heat produced by the electronic components will be the key to increase the overall performance.

Therefore, many electronic equipments rely on water or other cooling fluid since they have the ability to absorb higher capacity of heat and therefore, removing a large quantity of heat. But to insert liquid tracks within the circuitry, it involves the filling of the liquid as well as the complete drainage. It must work within a confined space. It must take every precaution in preventing any leakage, which will cause short-circuits. It affects the overall safety. It shows that this case involves a certain degree of danger.

On the other hand, there is another much safer method. It involves the filling of liquid nitrogen or cool air. Because of the great differences in the air temperatures, it'll reduce great amount of heat. But, this method is not only very costly, but also it must first drain the liquid condensation, to prevent the accumulation of the humidity, which may drip into the circuit components.

If there's an option of not having to cool the filling air and still be able to increase the performance of the heat dissipation, it'll not only guarantee the smooth circuit operation, preventing the unnecessary problems of higher energy consumption and humidity accumulation. It'll give more flexibility and options to choose the circuit components. To maximize the efficiency and performance of the electronic components is a subject worthy of studying.

### SUMMARY OF THE INVENTION

Therefore, one of the purposes of this invention is to provide a heatsink that can maximize the efficiently of cooling a heating device.

Another purpose of this invention is to provide a heatsink with a simple device that is easy to operate. Another purpose is to provide a low cost device that has the flexibility of choosing circuit components that can greatly reduce the heat.

Therefore, this invention, the top mount surface airflow heatsink can cover one heat device with a constant air feed supply. It receives the air feeds from an air compressing unit. Directing outward the heat generated by the heat device. The heatsink includes the following: an upper ceiling wall and a separate container, an air gap separates them with the heat device. The air current system is originated from the Reynolds Equation Re=(ρuₘd)/μ≧2,500; with σ being the fluid density, uₘ being the free-stream fluid velocity, d being the pipe distance or diameter, μ being the fluid viscosity.

This invention utilizes great volumes of air supply, forcing it to produce air turbulence, increasing the airflow between layers of air. It stabilizes the temperature in a short amount of time. Not only it is a simple device, the manufacturing cost is also very low, and there is no need to induce cooling agent to operate. There's no need to reduce the air humidity, therefore, preventing it from the dangers of an accidental leakage. It has an easy operation, built on a simple mechanism. At the same time, it fulfills the function of the heat reduction, avoiding unnecessary higher energy consumption, and it increases the use of the circuit components. It also increases the dependability and the stability of the electronic circuits. It solves all the previous problems and accomplishes the goals of this patent case.

### BRIEF DESCRIPTION OF THE DRAWINGS

The invention is generally shown by way of reference to the accompanying drawings:

FIG. 1, a traditional heatsink and microprocessor component of a circuit board;

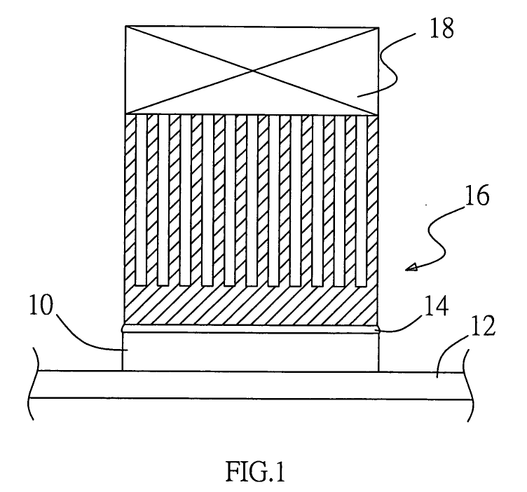

FIG. 2, U.S. Pat. No. 6,603,658 patent invention of a heatsink operational diagram;

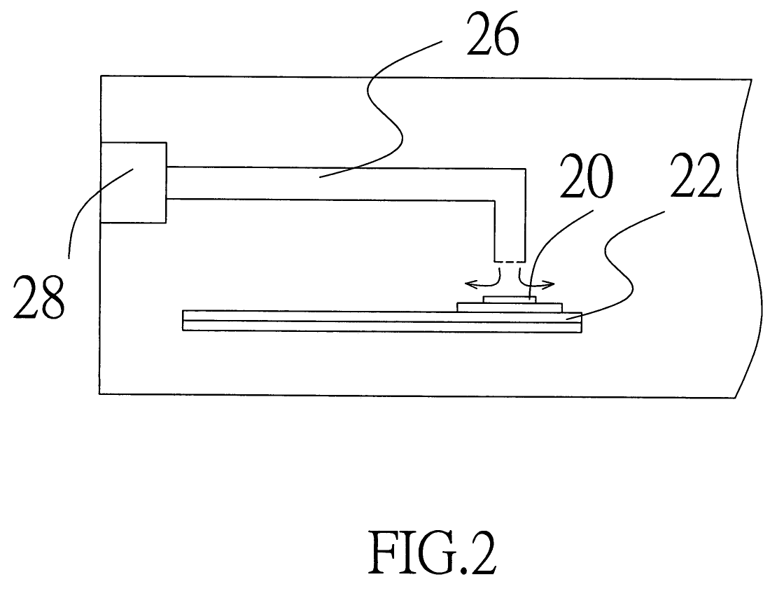

FIG. 3, the airflow diagram produced by the heatsink from FIG. 2;

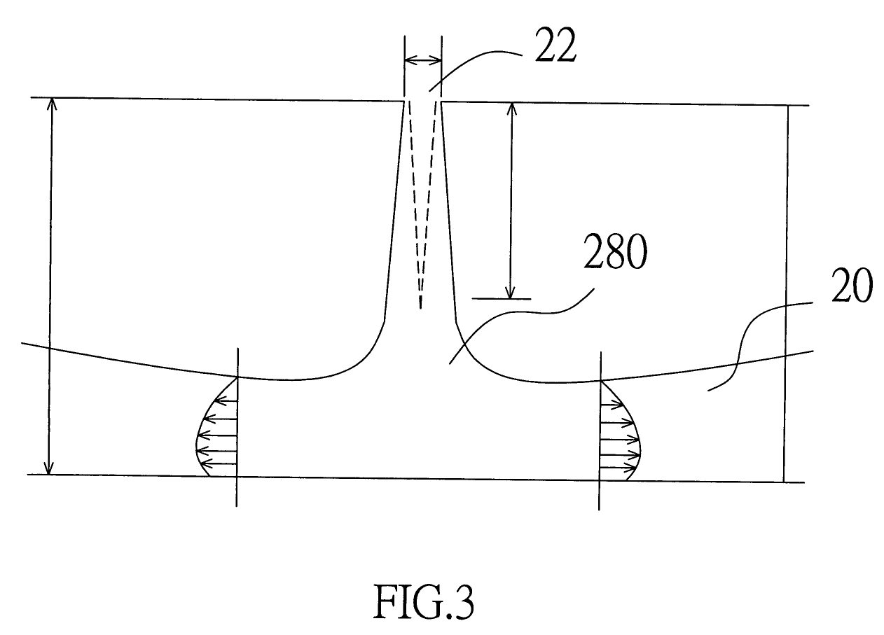

FIG. 4, the best case scenario 3-D diagram of the top mounted heatsink of this invention;

FIG. 5, display diagram of FIG. 4, with examples of air current flowing inside the air chamber;

FIG. 6, display diagram of FIG. 5, with different layers of air flowing inside the air chamber and the distribution of the air temperature;

FIG. 7, the second best case scenario, example of structure schematic drawing implementation;

FIG. 8, the third best case scenario, example of structure schematic drawing implementation; and

FIG. 9, the fourth best case scenario, example of structure schematic drawing implementation.

### DETAILED DESCRIPTION OF THE INVENTION

Regarding this invention and the previously mentioned technology, it will all be described in detail in the following diagrams.

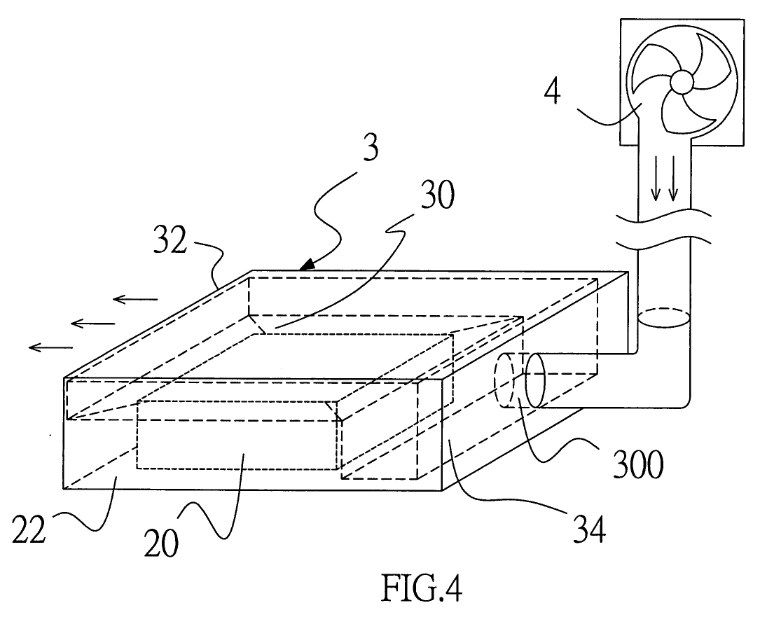

Regarding FIG. 4, a simple description of each component follows:

| Component | Description |
|---|---|
| 3 | top mount heat sink |
| 4 | air supply |
| 20 | heat device (microprocessor) |
| 22 | circuit board |
| 30 | airflow |
| 32 | ceiling wall |
| 34 | air separation chamber |
| 300 | connecting point |

Regarding all Figures, a description of the main components follows:

| Component | Description |
|---|---|
| 3, 3′, 3″ | top mounted heat sink |
| 3″′ | top mounted heat sink unit |
| 4 | compressing air unit |
| 10 | semi-conductor chip |
| 12, 22 | circuit board |
| 14 | cooling gel |
| 16 | heat sink fins |
| 18, 28 | fan |
| 20 | processor chip |
| 26 | air duct |
| 30 | airflow |
| 32 | top ceiling |
| 34 | separation compartment |
| 280 | air current |
| 300 | connecting pipe |
| 302 | lowest layer |
| 304, 306 | layer above |
| 308 | top layer |
| 380 | uniform |
| 381 | elliptical curve |
| 382 | air turbulence |
| 70, 80 | enclosure unit |
| 700 | multi-clip system |
| 702 | extended clip |
| 802 | angled-latches |
| 804 | buckles |
| 902 | fixed hole |
| 904 | side extensions with holes |
| 906 | screws |

The first implementation of the top mount surface airflow heatsink (3) as illustrated in FIG. 4, has an upper ceiling wall (32), a separation chamber (34). The separation chamber (34) includes the extension of the two side-walls that go all the way to the top, and a bottom surface wall. The bottom surface wall extends to the top opening of the heat device (20). It wraps around the heat device (20) and makes the air turbulence flow to the top mount surface airflow heatsink (3) securely place above the circuit board (22). The upper ceiling wall (32), the separation chamber (34) and the heat device (20) devise an air duct (30). The air duct (30) has a connecting point (300), which connects to the air feed of a fan (4).

The air coming from the fan (4) will enter through the connecting point (300) and continue through the air duct (30). The air duct (30) has a specific measurement of cross-section. It makes the airflows through the air duct (30) and is derived from the Reynolds Equation Re=(ρuₘd)/μ≧2,500; with ρ being the fluid density, uₘ being the free-stream fluid velocity, d being the pipe distance or diameter, μ being the fluid viscosity.

Therefore, the heat produced by the heat device (20), through the use of the top mount surface airflow heatsink (3), and the heat exchanges between the air currents in the air duct (30), will expel the heat produced by the heat device (20).

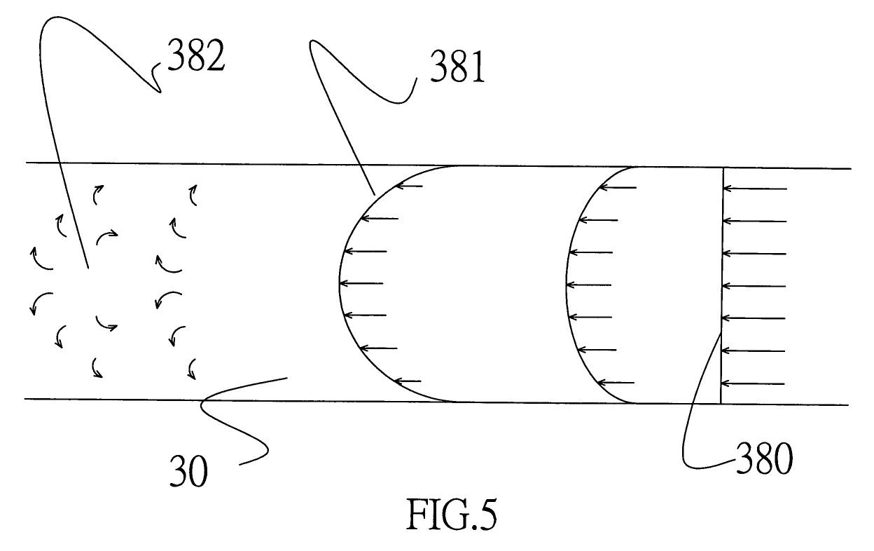

As illustrated on FIG. 5, a typical air current has a constant speed flowing into a channel. At first, the flowing speed will be as shown on the right of the diagram, with an uniform advancement (380). Later on, because of the friction between the air channel (30) and the flowing air, also because of the air viscosity effect, as the air current approaches the air channel (30), it makes the air flowing closer to the wall surface to slowdown, even stopping it altogether. Contrarily, the air flowing in the center of the air channel (30) do not get affected; which eventually will form an elliptical curve (381) as shown. On the other hand, if the flowing speed is too fast, or if the viscosity is low, it will make each air particle flow on different directions. It'll make different layers interact with one another, producing air turbulence (382).

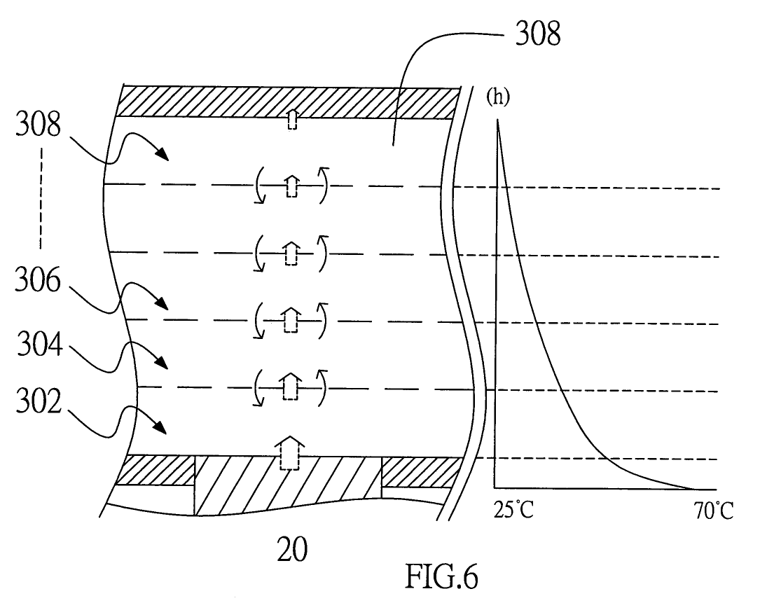

Further consideration for the internal and external temperatures of the air channel, as illustrated in FIG. 6; when heat device (20) located below the air channel (30), utilizing the direction of the air current, will carry the heat produced by the heat device (20) toward the air channel (30). It'll force the room temperature air pass through the air channel (30), moving from right to left. If the air inside the air channel (30), remain in good flowing manner as shown in dashed line, the lowest layer of air (302) in the air channel (30) will initiate a heat exchange. The lowest layer of air (302) will slowly absorb the heat and rise. The heat exchange rate will slow down. The lowest layer of air (302) will interact less with the upper layers (304) and (306), it'll make the heat exchange less frequent. It'll make the most upper layer of air (308) remain in room temperature, but it does not help the increasing temperature from the lowest layer of air (302).

Inversely, if the air current becomes turbulent then the layers of air will become very active. The lowest layer of air (302) will absorb part of the heat coming from the air channel (30). It'll then move upward to the upper layers (304), (306). The room temperature air, of the layers (304) and (306) will move downward. Therefore, maintaining a difference in temperatures between the air from lowest layer (302) and the air in the air channel (30). It increases the heat exchange. As illustrated on the right of the FIG. 6, when the temperature of the inflow air reaches 25 degrees Celsius, the temperature of the airflow may remain in the 70 degrees Celsius. Which makes the air inside air channel (30) absorb the heats from upper layers (308), (306), (304) to the lowest layer (302) and moving them altogether.

To prove the above theory, the inventor used two 40 watts (each) resistors to simulate the heat device. Without a heatsink, temperature of the resistors can reach to 170 degrees Celsius. As mentioned previously, if comparing instead, with semi-conductor devices, under the same heat condition, they'll already be burned out. On the other hand, without using induction of air, instead, using the top mount heatsink from this patent alone, as heat conducting unit, the temperature of the operating resistors can reach up to 110 degrees Celsius. But using induction of compressed air as this patent intends, the temperature of the resistors have decreased to 70 degrees Celsius. The current single chip electronic component does not use more than 4 or 5 watts. Using the prototype of this patent's top mount heatsink, can easily safeguard at least 20 circuit components. It'll allow a smooth operation under a safe environment.

Especially, separating the air flowing from upward to downward, the difference in temperatures between the upward heat device and the downward heat device is less than 2 degrees Celsius. It insinuates that the air inside the cooling device is able to remove the heat, preventing the heat accumulation. Besides, the induced air is of the room temperature. Not only it does not have the humidity problem, it can really remove the heat out of the heatsink. It'll let the heating air inside the electronic components to disperse without having to worry about the installation safety issues of the cooling fluid devices.

On the other hand, there are different heat conducting materials that may differ slightly by the thermal resistance, like copper and aluminum. If they are used on the same experiment, you'll discover that the effect of the reduced temperature is not much different. In other words, the top mount heatsink presented in this case, can lead to low cost and the easy manufacturing of the metals, but it does not need to be restricted by the quality of the materials.

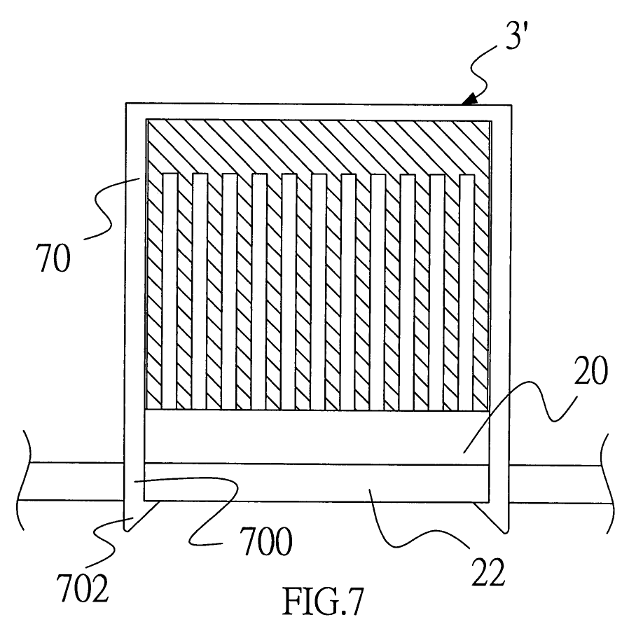

Certainly, the technician who is familiar with the technology can easily understand. The preceding implementation forms the air turbulence chamber and can be shown with the optimal performance under different ways. As illustrated by the FIG. 7, the second best case scenario, shows the top mount surface airflow heatsink (3′) and circuit board (22), microprocessor (20) both positioned in the same circuit board (22) to form the multi-clip system (700), the enclosure unit (70) is securely attached to the top mount surface airflow heatsink's (3′) main body; The enclosure unit's (70) base has the extended clip (702), the extended clip (702) forms the corresponding multi-clip system (700), which secures the top mounted heatsink (3′) to the circuit board (22). As long as the airflow, with the Reynolds number remains above 2500, the air current becomes the air turbulence then, it'll achieve the same result.

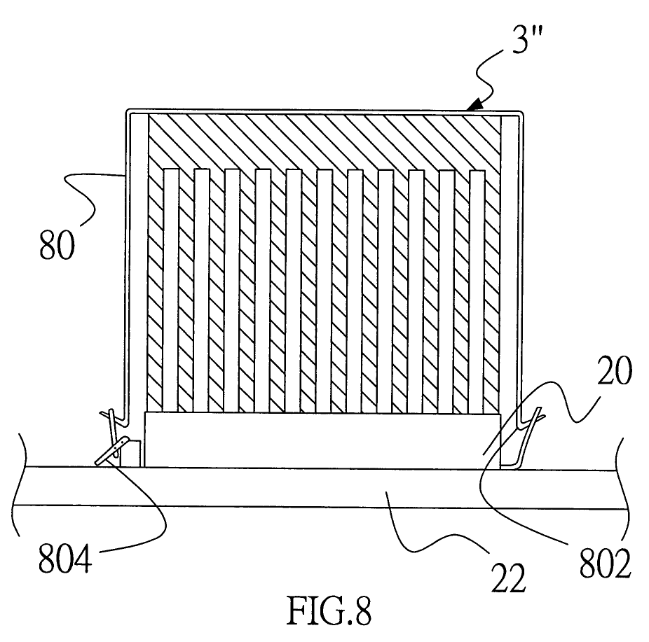

As illustrated in FIG. 8, the third best case scenario, the enclosure unit (80) is securely attached to the top mounted heat sink's (3″) main body. The bottom of the enclosure unit (80) has multiple angled-latches (802); by attaching to the top of the circuit board (22) using the angled-latches and the buckles (804) it's another way of securing the heat sink than the previously mentioned case scenario. As long as the air current is enabled to form the air turbulence, it'll be able to achieve the heat dissipation required.

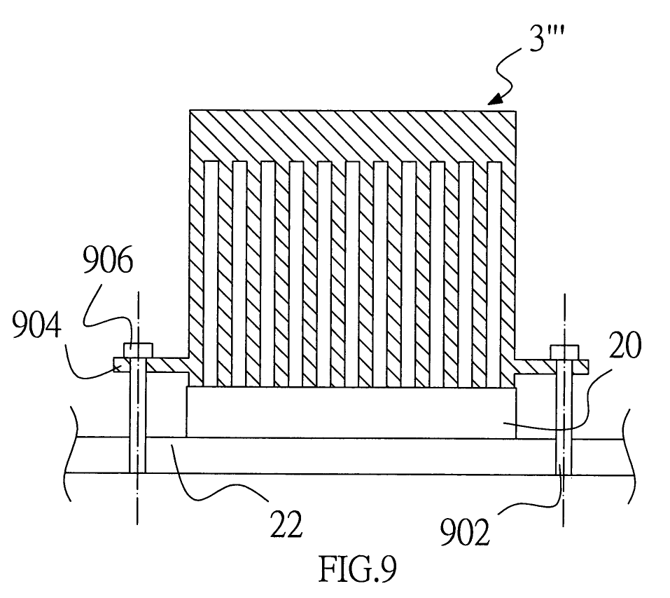

As illustrated in FIG. 9, it's possible to secure the top mounted heat sink, by using another way of installation. The fourth best case scenario, of securing the top mounted surface airflow heatsink (3′″) uses the multiple side extensions with holes (904), and the multiple fixed holes (902) in the circuit board. By matching the position of the holes and securing it with screws (906). Using the screws (906) the circuit board (22) and the top mount surface airflow heatsink (3′″) are securely attached together. Even though, the way of attaching is different, it assures the formation of the air turbulence chamber, letting the heat produced by the processor to be dissipated by the air turbulence. It uses the unlimited supply of the lower temperature air to cool down the temperature of the processor.

This case uses the air turbulence formed inside the air chamber, guaranteeing a massive intermolecular heat exchange, causing the lowest layer of air elevate due to differences in air temperature. By using the air cooling effect it increases the performance efficiency. The device is so simple that there's no need to worry about a short circuit. The production cost is low. Especially, when after the heat dissipation performance is increased, the circuit designers have the freedom to choose higher performance circuit components. They don't have to worry about the over heating problem which may lead to unstable circuit boards. The purpose of this patent device is to achieve the overall performance of the electronic circuit platforms

The above mentioned, are the best case scenarios for this invention. It cannot be limited to just these cases. Namely the overall information in this invention, the patent application, the scope and the invention instruction manual, even the slightest changes, all should still be covered by the scope of this invention patent.

What is claimed is:

1. A top mount surface airflow heatsink for semiconductor chips. It requires a connection to a device which can provide a constant feed of air. It uses the supply of airflow to dissipate the heat produced by the semiconductor chip. It is installed together with the semiconductor chip in the circuit board. The top mounted heatsink includes: the top mounted heatsink kit. This kit includes:
Ceiling wall;
Ceiling wall extension, providing a surface gap between the ceiling wall and the semiconductor chip. The ceiling wall together with the semiconductor chip devises an airflow chamber. The airflow system is originated from an air supply unit and is derived from the Reynolds Equation Re=(ρuₘd)/μ≧2,500; with ρ being the fluid density, uₘ being the free-stream fluid velocity, d being the pipe distance or diameter, μ being the fluid viscosity.

2. The above described scope of claim 1, the top mount surface airflow heatsink, the separate extension of the ceiling and 2 side surface walls, and the bottom surface wall which forms an opening or gap opposite the semiconductor chip.

3. The above described scope of claim 1, the top mount surface airflow heatsink and all the installation accessories included for securing the heatsink to the circuit board.

4. The above described scope of claim 3, the top mount surface airflow heatsink, the multiple screw holes, the attaching installation kit includes:
The heatsink attaching unit;
The attaching clips at the bottom of the attaching unit.

5. The above described scope of claim 3, the top mount surface airflow heatsink, the attaching kit, which includes:
The heatsink attaching unit; the angled-latches and the buckles to secure it to the circuit board.

6. The above described scope of claim 3, the top mount surface airflow heatsink, the attaching screw holes in the circuit board, the bottom side extension of the top mount heatsink with screw holes, and the screws securing the heatsink to the circuit board.

7. A type of heatsink component, which dissipates the heat generated by the microprocessor. The component includes:
Top mount surface airflow heatsink. The heatsink includes:
Ceiling wall;
Ceiling wall extension, which maintains an opening between the ceiling wall and the microprocessor, devising an air chamber;
Connecting the air chamber, the air current derived from the Reynolds Equation Re=(ρuₘd)/μ≧12,500; with ρ being the fluid density, uₘ being the free-stream fluid velocity, d being the pipe distance or diameter, μ being the fluid viscosity.

8. The above described scope of claim 7, the heatsink component, the top mount heatsink in addition to the attaching installation kit.

9. The above described scope of claim 7, the heatsink component, and the air feeding system, a fan.

10. A top mount surface airflow heatsink for semiconductor chips, wherein:
said heatsink requires a connection to a device which can provide a constant feed of air;
said heatsink uses the supply of airflow to dissipate the heat produced by the semiconductor chip;
said heatsink is installed together with the semiconductor chip in a circuit board;
said top mounted heatsink includes a top mounted heatsink kit;
the kit includes a ceiling wall and a ceiling wall extension, providing a surface gap between the ceiling wall and the semiconductor chip;
the ceiling wall together with the semiconductor chip devises an airflow chamber; and
the airflow system is originated from an air supply unit and is derived from the Reynolds Equation Re=(ρuₘd)/μ≧2,500, with ρ being the fluid density, uₘ being the free-stream fluid velocity, d being the pipe distance or diameter, and μ being the fluid viscosity.

11. The above described claim 10 for a top mount surface airflow heatsink including:
the separate extension of the ceiling and two side surface walls; and
a bottom surface wall which forms an opening or gap opposite the semiconductor chip.

12. The above described claim 10 for a top mount surface airflow heatsink including all the installation accessories included for securing the heatsink to the circuit board.

13. The above described claim 12 for a top mount surface airflow heatsink including multiple screw holes, wherein the attaching installation kit includes:
a heatsink attaching unit; and
attaching clips at the bottom of the attaching unit.

14. The above described claim 12 for a top mount surface airflow heatsink, wherein the attaching kit includes:
a heatsink attaching unit; and
angled-latches and buckles to secure said heatsink to the circuit board.

15. The above described claim 12 for a top mount surface airflow heatsink, the circuit board having attaching screw holes, the bottom side extension of the top mount heatsink having screw holes, and wherein screws secure the heatsink to the circuit board.

16. A heatsink component which dissipates the heat generated by a microprocessor, the component including:
a top mount surface airflow heatsink; where said heatsink includes:
a ceiling wall; and
a ceiling wall extension, which maintains an opening between the ceiling wall and the microprocessor, devising an air chamber;
wherein said heatsink is connected to the air chamber, the air current derived from the Reynolds Equation Re=(ρuₘd)/μ≧2,500, with ρ being the fluid density, uₘ being the free-stream fluid velocity, d being the pipe distance or diameter, and μ being the fluid viscosity.

17. The above described claim 16 for a heatsink component, including a top mount heatsink and an attaching installation kit.

18. The above described claim 16 for a heatsink component, including an air feeding system and a fan.

19. A heatsink for a heat-producing device, wherein:
the heatsink has a connection to an air supply unit which provides an airflow;
the heatsink uses the airflow to dissipate the heat produced by the heat-producing device;
the heatsink has a ceiling wall and a ceiling wall extension which provides an air gap between the ceiling wall and the heat-producing device;
the ceiling wall and the heat-producing device form an airflow chamber; and
the airflow is derived from the Reynolds Equation Re=(ρuₘd)/μ≧2,500, with ρ being the fluid density, uₘ being the free-stream fluid velocity, d being the pipe distance or diameter, and μ being the fluid viscosity.

20. The heatsink of claim 19, wherein the heat-producing device is a semiconductor chip.

21. The heatsink of claim 19, wherein the air supply unit provides a constant feed of air

22. The heatsink of claim 19, wherein the heatsink is adapted to be installed together with the heat-producing device on a circuit board.

23. The heatsink of claim 19, wherein the heatsink is mounted on top of the heat-producing device.

24. A heatsink for a heat-producing device comprising:
a heatsink main body having a bottom surface which forms a ceiling wall;
a ceiling wall extension which forms an airflow chamber between the ceiling wall and the heat-producing device; and
an air supply unit connected to the heatsink which provides turbulent airflow through the airflow chamber;
wherein the turbulent airflow flows across the surface of the heat-producing device to dissipate the heat produced by the heat-producing device.

25. The heatsink of claim 24 wherein the turbulent airflow is characterized by the Reynolds Equation Re=(ρuₘd)/μ≧22,500, with ρ being the fluid density, uₘ being the free-stream fluid velocity, d being the pipe distance or diameter, and μ being the fluid viscosity.

26. The heatsink of claim 24 wherein the turbulent airflow is characterized by a ratio of inertial forces to viscous forces greater than or equal to 2,500.

27. The heatsink of claim 24 wherein the heat-producing device is a microprocessor.

28. The heatsink of claim 24 further comprising:
two side surface walls, and
a bottom surface wall;
wherein the two side surface walls and bottom surface wall provide a gap allowing turbulent airflow across the surface of the heat-producing device.

29. The heatsink of claim 28 wherein the heat-producing device is mounted on a circuit board and the circuit board forms the bottom surface wall.

30. The heatsink of claim 24 wherein the heat-producing device is mounted on a circuit board, the heatsink is secured to the circuit board, and the heatsink wraps around the heat-producing device.

31. The heatsink of claim 30 wherein the circuit board forms a wall of the air chamber.

32. The heatsink of claim 30 further comprising means for securing the heatsink to the circuit board.

33. The heatsink of claim 30 further comprising an installation kit including installation accessories for securing the heatsink to the circuit board.

34. The heatsink of claim 33, wherein the circuit board has multiple screw holes, the heatsink is attached to the circuit board with screws that match the position of the screw holes, and the installation kit further comprises a heatsink attaching unit which includes attaching clips.

35. The heatsink of claim 33, wherein the installation kit further comprises:
a heatsink attaching unit; and
angled-latches and buckles to secure the heatsink to the circuit board.

36. The heatsink of claim 33, wherein the circuit board has holes and the lower portion of the ceiling wall extension has holes, wherein the holes can be aligned and the heatsink secured to the circuit board with fasteners that pass through the holes.

37. A heatsink component for a heatsink and a heat-generating device, the heatsink component including:
a ceiling wall extension; and
an air duct connecting the heatsink component with an air apply;
wherein a surface of the heatsink forms a ceiling wall above the heat-generating device, the ceiling wall extension maintains an opening which forms an air chamber between the ceiling wall and the heat-generating device, and a turbulent air current flows from the air supply through the air duct into the air chamber.

38. The heatsink component of claim 37 wherein the turbulent airflow is characterized by the Reynolds Equation Re=(ρuₘd)/μ≧2,500, with ρ being the fluid density, uₘ being the free-stream fluid velocity, d being the pipe distance or diameter, and μ being the fluid viscosity.

39. The heatsink component of claim 37 wherein the heatsink is mounted on top of the air chamber and the heatsink component wraps around the heat-generating device.

40. The heatsink component of claim 37 further comprising an installation kit including installation accessories for securing the heatsink to the heat-generating device.

41. The heatsink component of claim 37 further comprising a fan, wherein air is directed by the fan to flow through the air duct into the air chamber.
